(19) United States
(12) Patent Application Publication
(10) Pub. No.: US 2009/0102530 A1
(43) Pub. Date: Apr. 23, 2009

(54) Reference pulse discrimination method

(76) Inventor: Pascal Desbiolles, Thorens-Glieres (FR)

Correspondence Address: ARENT FOX LLP, 1050 CONNECTICUT AVENUE, N.W., SUITE 400, WASHINGTON, DC, 20036, US

(21) Appl. No.: 11/920,622

(22) PCT Filed: May 19, 2006
(86) PCT No.: PCT/FR2006/001151

§ 371 Date: Mar. 27, 2008

(30) Foreign Application Priority Data
May 19, 2005 (FR) 0505035

(51) Int. Cl. H03K 12/00

(52) U.S. Cl. 327/184

(57) ABSTRACT

The invention relates to a method of forming a reference pulse Iᵣ from three signals, SIN, COS and REF, in which: the REF signal is compared with a threshold value such as to form a digital signal S1 comprising windows F having a width that is a function of the half period of signal REF; and signals SIN and COS are compared in order to form a digital signal S2 comprising, for each period, a pulse I and a combination of the pre-formed digital signals (S1, S2) such as to discriminate the reference pulse Iᵣ. The invention also relates to a device for determining a reference state of an element that is rotating in relation to a fixed structure, comprising a treatment device that can perform one such method.

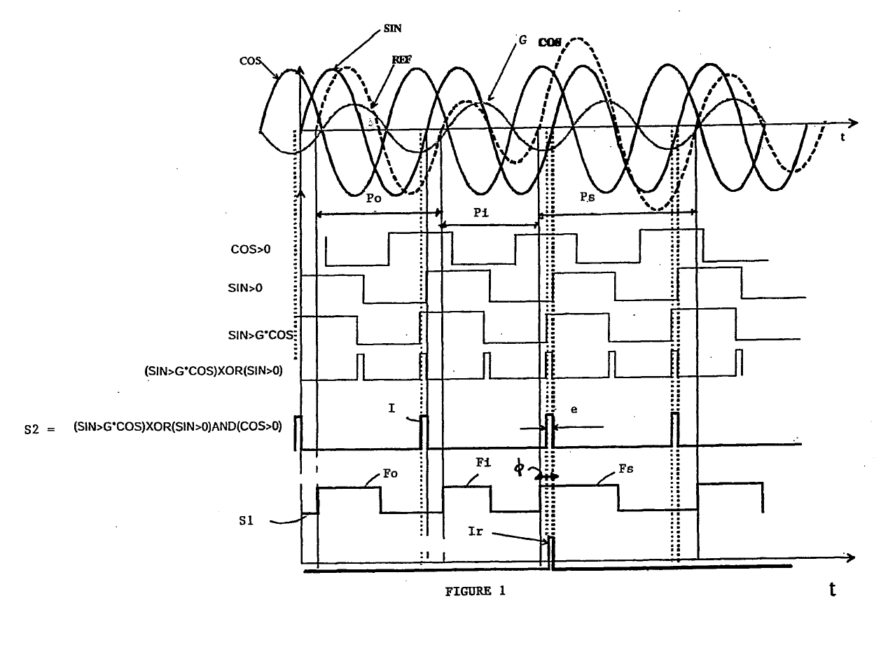

The invention relates to a method of forming a reference pulse using three signals, SIN, COS and REF, which are temporally pseudo-sinusoidal and have the same nominal period, the SIN and COS signals being in quadrature, the REF signal being offset by an angle φ in relation to the SIN signal, and the REF signal having a singular period. The invention also relates to a device for determining a reference state of a rotating member in relation to a fixed structure, which comprises a processing device capable of implementing such a method.

According to examples of use, the device can determine the absolute angular position of the rotating member in relation to the fixed structure, in particular such as described in document FR-2 856 147, or control an electronic-switching motor such as described in documents FR-2 845 212 or FR-2 845 213.

In fact, the formation of a reference pulse allows said reference position to be detected by indexing it to a reference angular position of the rotating member.

Documents FR-2 769 088 and EP-0 871 014 describe methods for forming a reference pulse using predefined SIN, COS and REF signals.

In practice, these methods can be limited in the event of signal amplitude variations, for example under the effect of operating temperature differences or dispersions in the positioning of the sensitive elements intended to supply said signals.

The invention aims, in particular, to overcome this limitation by improving the sturdiness of the method for forming a reference impulse against possible signal amplitude variations, as well as improving the known determination devices.

For this purpose, according to a first aspect, the invention relates to a method of forming a reference pulse Iᵣ using three signals, SIN, COS and REF, which are temporally pseudo-sinusoidal and have the same nominal period P₀, the SIN and COS signals being in quadrature, the REF signal being offset by an angle φ in relation to the SIN signal, and the REF signal having a singular period Pₛ, said method including the following steps:

comparing the REF signal with a threshold value in order to form a digital signal S1 comprising windows F with a width according to the period of the REF signal;

comparing the SIN and COS signals in order to form a digital signal S2 comprising, for each period, a pulse I with a width limited to a value that is lower than that corresponding to the offset φ, said pulses being positioned so as to be included in the window F_{S} corresponding to the singular period and to be excluded from the other windows;

combining the previously formed digital signals S1, S2 in order to discriminate the reference pulse Iᵣ corresponding to the singular period P_{S}.

According to a second aspect, the invention provides a device for determining a reference state of a rotating member in relation to a fixed structure, said device comprising:

a coder designed to be solidly attached to the rotating member, said coder being arranged so as to supply three signals, SIN, COS and REF, which are temporally pseudo-sinusoidal and have the same nominal period, the SIN and COS signals being in quadrature, the REF signal being offset by an angle φ in relation to the SIN signal, and the REF signal having at least one singular period corresponding to a reference state;

a fixed sensor at read range from the coder, said sensor being arranged to supply the SIN, COS and REF signals;

a device for processing the SIN, COS and REF signals which is capable of forming a reference pulse according to the method presented above, in order to determine the state by detecting the corresponding reference pulse.

Further objectives and advantages of the invention will become apparent from the following description, made in reference to the appended FIGURE, which shows the signals used to implement the method according to one embodiment thereof.

The invention relates to a device for determining the reference state of a rotating member in relation to a fixed structure. In one example of application, the reference state is an absolute angular position of the rotating member in relation to the fixed structure, for example of the steering column of an automobile vehicle in relation to the chassis of said vehicle.

However, the invention is not at all limited to such a particular application, and can be used in any other application in which a reference angular position of a rotating member needs to be determined, in particular for controlling an electronic-switching motor.

The determination device comprises a coder designed to be solidly attached in rotation to the rotating member. According to the described embodiment, the coder is formed by a magnetic ring comprising a main multipolar track and a reference multipolar track, which are concentric, said tracks comprising a succession of north and south poles with constant polar width.

Moreover, the reference track comprises a magnetic transition that is different from the others, in order, for example, to form a magnetic singularity formed by a pair of poles of different widths to the others. Such an embodiment of the coder is, for example, described in documents FR-2 769 088 and EP-0 871 014. According to one embodiment, the reference track can comprise several magnetic singularities, distributed along said track.

Such a coder allows three signals (hereinafter called SIN, COS, REF) to be supplied by means of the main track for the SIN and COS signals and by means of the reference track for the REF signal.

As shown in the FIGURE, the SIN, COS and REF signals are temporally pseudo-sinusoidal and have the same nominal period P₀. Pseudo-sinusoidal is understood to mean that the signal can be approximated by a sine curve.

Furthermore, the SIN and COS signals are in quadrature and the REF signal is offset by an angle φ in relation to the SIN signal. Moreover, due to the presence of the magnetic singularity, the REF signal has a singular period Pₛ. More specifically, in the described embodiment, the singularity induces the presence of a period Pᵢ with a lower value than P₀ and of the period Pₛ which has a higher value than that of P₀.

To determine the reference state, the singular period Pₛ is arranged to correspond with said reference state. For this reason, the singularity can be indexed with a reference angular position in the case of a device for determining the absolute angular position of the rotating member. In this application, the SIN and/or COS signals can be used to discover the relative angular position of the rotating member in an incremental fashion, and the detection of the reference pulse allows this position to be compensated in relation to the absolute position.

The determination device also comprises a fixed sensor at read range from the coder, said sensor being arranged to supply the SIN, COS and REF signals.

For this purpose, in the described embodiment, the sensor comprises at least two sensitive elements arranged at air-gap distance from the main track to supply the SIN and COS signals. In one example of an embodiment, the sensor comprises a plurality of sensitive elements aligned as described in document FR-2 792 403. Moreover, the sensor comprises at least one sensitive element placed at air-gap distance from the reference track to supply the REF signal.

The determination device also comprises a device for processing the SIN, COS and REF signals, which is capable of forming a reference pulse Iᵣ according to the method described below so as to determine the corresponding reference state by detecting the reference pulse.

The method of forming a reference pulse Iᵣ using three signals, SIN, COS and REF comprises a step of comparing the REF signal with a threshold value in order to form a digital signal S1 comprising windows F with a width according to the alternation of the REF signal.

In the embodiment shown, the REF signal is compared with the average value of said signal, which is equal to zero.

The formation method also comprises a step of comparing the SIN and COS signals, in order to form a digital signal S2 comprising, for each period, a pulse I with a width limited to a value e which is lower than the value of the offset φ. The pulses I are positioned so as to be included in the window F_{S} corresponding to the singular period Pₛ and to be excluded from the windows F₀ corresponding to the nominal period P₀, as well as from the narrower window Fᵢ, which corresponds to the period Pᵢ.

In the embodiment shown, the amplitude of the COS signal is adjusted by a gain G so as to limit the width of the pulses and the positioning of the same. Moreover, the comparison is made by calculating the following: S2=(SIN>GCOS)XOR(SIN>0)AND(COS>0), XOR being the “exclusive or” operator and AND being the conjugation operator.

Finally, the method allows the signals S1 and S2 to be combined in order to discriminate the reference pulse Iᵣ corresponding to the singular period, said combination being made by the AND operator. This discrimination is made possible by the fact that the width e of the pulses is kept at a value lower than that corresponding to the offset φ, which allows all the pulses I to be positioned in relation to the windows according to the invention.

Moreover, the width of the pulses can be limited in order to take into consideration the influence of the air-gap variations between the sensitive elements and the multi-polar tracks, as well as temperature variations. In fact, such variations can produce digital signal phase modulations requiring an adjustment of the width of the pulses in order to maintain the position of said pulses in relation to the windows in all operating conditions.

If the coder comprises several magnetic singularities, which is to say that the REF signal comprises several singular periods Pₛ, the method allows the reference pulses Iᵣ corresponding to each of said singular periods to be discriminated.

By implementing the method according to the invention, the amplitude variations of the SIN, COS and/or REF signals do not affect the discrimination of the reference pulse, since:

these variations barely modify the signal S1; and

the formation of the signal S2 according to the invention is independent from said amplitudes.

Therefore, the method according to the invention provides great sturdiness in relation to operating temperature variations and/or dispersion of the positions of the sensitive elements at air-gap distance from the multipolar tracks.

1. Method of forming a reference pulse Iᵣ using three signals, SIN, COS and REF, which are temporally pseudosinusoidal and have the same nominal period Pₒ, the SIN and COS signals being in quadrature, the REF signal being offset by an angle ø in relation to the SIN signal, and the REF signal having a singular period Ps, said method including the following steps:
comparing the REF signal with a threshold value in order to form a digital signal S1 comprising windows F with a width according to the alternation of the REF signal;
comparing the SIN and COS signals in order to form a digital signal S2 comprising, for each period, a pulse I with a width limited to a value that is lower than that corresponding to the offset ø, said pulses being positioned so as to be included in the window Fₛ corresponding to the singular period and to be excluded from the other windows;
combining the previously formed digital signals S1, S2 in order to discriminate the reference pulse Iᵣ corresponding to the singular period. Pₛ.

2. Method according to claim 1, wherein the amplitude of the COS signal is adjusted by a gain G so as to limit the width of the pulses I and the positioning of the same in relation to the windows.

3. Method according to claim 1, wherein the step of comparing the SIN and COS signals is performed by calculating: (SIN>COS)XOR(SIN>0)AND(COS>0), XOR being the “exclusive or” operator and AND being the conjugation operator.

4. Method according to claim 1, wherein the REF signal is compared with the average value of said signal.

5. Method according to claim 4, wherein the threshold value is equal to zero.

6. Method according to claim 1, wherein the combination is made by the AND operator.

7. Method according to claim 1, wherein the REF signal comprises several singular periods, said method allowing the reference pulses corresponding to each of the singular periods to be discriminated.

8. Device for determining the reference state of a rotating member in relation to a fixed structure, said device comprising:
a coder designed to be solidly attached to the rotating member, said coder being arranged so as to supply three signals, SIN, COS and REF, which are temporally pseudosinusoidal and have the same nominal period, the SIN and COS signals being in quadrature, the REF signal being offset by an angle ø in relation to the SIN signal, and the REF signal having at least one singular period corresponding to a reference state;
a fixed sensor at read range from the coder, said sensor being arranged to supply the SIN, COS and REF signals;
a device for processing the SIN, COS and REF signals which is capable of forming a reference pulse by
comparing the REF signal with a threshold value in order to form a digital signal S1 comprising windows F with a width according to the alternation of the REF signal;
comparing the SIN and COS signals in order to form a digital signal S2 comprising, for each period, a pulse I with a width limited to a value that is lower than that corresponding to the offset ø, said pulses being positioned so as to be included in the window Fₛ corresponding to the singular period and to be excluded from the other windows;
combining the previously formed digital signals S1, S2 in order to discriminate the reference pulse Iᵣ corresponding to the singular period. Pₛ, in order to determine the state by detecting the corresponding reference pulse.

9. Device according to claim 8, characterised in that the coder is formed by a magnetic ring comprising a main multipolar track and a reference multipolar track, which are concentric, said tracks comprising a succession of north and south poles with constant polar width, the singular period being made by a magnetic transition that is different to the others.

10. Device according to claim 9, characterised in that the sensor comprises at least two sensitive elements arranged at air-gap distance from the main track to supply the SIN and COS signals, and at least one sensitive element placed at air-gap distance from the reference track to supply the REF signal.

11. Method according to claim 2, wherein the step of comparing the SIN and COS signals is performed by calculating: (SIN>COS)XOR(SIN>0)AND(COS>0), XOR being the “exclusive or” operator and AND being the conjugation operator.

12. Method according to claim 2, wherein the REF signal comprises several singular periods, said method allowing the reference pulses corresponding to each of the singular periods to be discriminated.

13. Method according to claim 3, wherein the REF signal comprises several singular periods, said method allowing the reference pulses corresponding to each of the singular periods to be discriminated.

14. Method according to claim 4, wherein the REF signal comprises several singular periods, said method allowing the reference pulses corresponding to each of the singular periods to be discriminated.

15. Method according to claim 5, wherein the REF signal comprises several singular periods, said method allowing the reference pulses corresponding to each of the singular periods to be discriminated.

16. Method according to claim 6, wherein the REF signal comprises several singular periods, said method allowing the reference pulses corresponding to each of the singular periods to be discriminated.

17. Method according to claim 11, wherein the REF signal comprises several singular periods, said method allowing the reference pulses corresponding to each of the singular periods to be discriminated.
